(19) United States
(12) Patent Application Publication
(10) Pub. No.: US 2026/0333917 A1
(43) Pub. Date: Oct. 22, 2026

(54) IMAGE SENSOR DEVICE AND MANUFACTURING METHOD THEREOF

(71) Applicant: Taiwan Semiconductor Manufacturing Company, Ltd., Hsinchu (TW)

(72) Inventors: Ming-Yu Kuo, Tainan City (TW); Hung-Chang Chang, Tainan City (TW); Jiech-Fun Lu, Tainan County (TW)

(73) Assignee: Taiwan Semiconductor Manufacturing Company, Ltd., Hsinchu (TW)

(21) Appl. No.: 19/182,577

(22) Filed: Apr. 17, 2025

(51) Int. Cl. H10F 39/00; H10F 39/18

(52) U.S. Cl. CPC H10F 39/807; H10F 39/014; H10F 39/018; H10F 39/182; H10F 39/809

(57) ABSTRACT

An image sensor device includes a substrate, photodetectors, and a backside deep trench isolation (BDTI) structure. The substrate includes a front side, a back side opposite to the front side, and pixel regions between the front side and the back side. The photodetectors are disposed in the pixel regions, and the BDTI structure is disposed at a boundary of the respective pixel region. The BDTI structure includes a first portion and second portions, the first portion extends from the back side of the substrate to a first height within the substrate, and the respective second portion includes a second height greater than the first depth. A center line of the first portion is substantially aligned with a center line of the respective second portion in a plan view.

### BACKGROUND

Many modern-day electronic devices (e.g., smartphones, digital cameras, biomedical imaging devices, automotive imaging devices, etc.) include image sensors for capturing images. The respective image sensor includes photodetectors configured to absorb incident radiation and output electrical signals corresponding to the incident radiation. The photodetectors are often spaced from one another by a deep trench isolation structure. Although existing image sensors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9A, 10, 11A and 12-13 are schematic cross-sectional views of various stages of manufacturing an image sensor device, in accordance with some embodiments.

FIG. 9B is a schematic perspective view of the structure taken along the reference cross section A-A’ of FIG. 9A, in accordance with some embodiments.

FIG. 11B is a schematic plan view of the structure taken along the reference cross section B-B’ of FIG. 11A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the case of the CMOS image sensor device, device scaling may reduce the dimensions of the pixel to, for example, less than 0.4 microns. For such device, back-side deep trench isolation (BDTI) structures having different depths are employed to separate the pixel regions. For example, the deeper one of the BDTI structures is included in the image sensor device to improve the full well capacity (e.g., the amount of charge a photodetector can accumulate before saturation) of the photodetector and prevent leakage current. In some embodiments, a twice-photolithography-twice-etch process is performed to form the BDTI structures with different depths. However, such process involves long process times, high costs, and concern of trench-to-trench overlap. Thus, better methods are needed to form the BDTI structures with different depths.

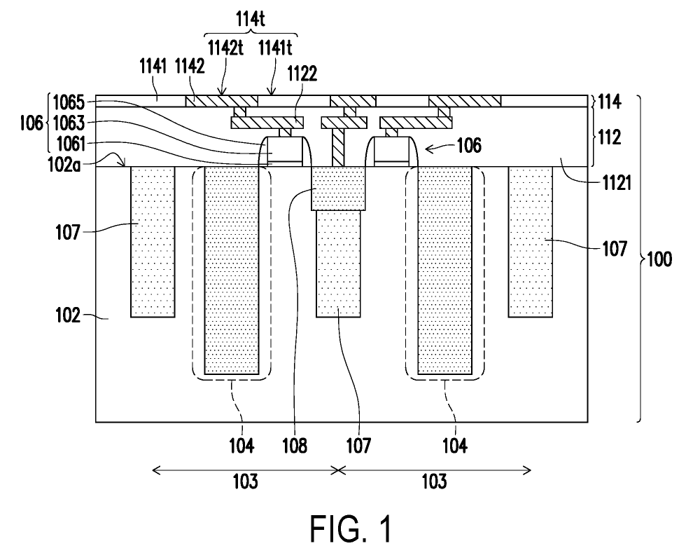

FIGS. 1-13 are schematic views of various stages of manufacturing an image sensor device, in accordance with some embodiments. Referring to FIG. 1, a first tier 100 is provided. For example, the first tier 100 includes a plurality of photodetectors 104 formed in a substrate 102. The substrate 102 may include a semiconductor substrate (e.g., silicon substrate, SiGe substrate, GaAs substrate, etc.), a silicon-on-insulator (SOI) substrate, or some other semiconductor substrate that is capable of generating a charge from photons of incident light. In some embodiments, the substrate 102 includes a semiconductor wafer or one or more die on a wafer, as well as any other type of semiconductor and/or epitaxial layers formed thereon and/or otherwise associated therewith.

The substrate 102 may include a plurality of pixel regions 103 arranged within the substrate 102 in an array including rows and/or columns. The term “pixel” may refer to a unit cell containing features (e.g., a photodetector and associated circuitries) for converting electromagnetic radiation to electrical signal. Each pixel may include a photodetector for recording an intensity or brightness of light and transistors (e.g., a transfer transistor, a reset transistor, a source-follower transistor, a select transistor, another suitable transistor, or combinations thereof). The circuitry (e.g., readout circuitry, control circuitry, etc.) may be coupled to the pixel array to provide an operating environment for the pixels and support external communications with the pixels. In some embodiments, the photodetectors 104 are in the pixel regions 103. The photodetectors 104 may include photodiodes, complimentary metal-oxide-semiconductor (CMOS) image sensors, charged coupling device (CCD) sensors, active sensors, passive sensors, and/or other sensors. The pixel regions 103 may be designed having various sensor types. The respective photodetector 104 may include one or more doped layer(s) and is configured to absorb photons of incident light. For example, the absorption of photons causes the photodetector 104 to accumulate a charge (referred to as a photocurrent) due to the photoelectric effect, and the photons may bombard the photodetector 104 to cause emission of electrons in the photodetector 104.

In some embodiments, the first tier 100 includes a plurality of transfer gates 106 formed on a front side 102a of the substrate 102. For example, the respective transfer gate 106 includes a gate dielectric layer 1061 disposed on the front side 102a of the substrate 102, a gate electrode layer 1063 formed on the gate dielectric layer 1061, and sidewall spacers 1065 formed on opposing sides of the gate electrode layer 1063 and opposing sidewalls of the gate dielectric layer 1061. In some embodiments, one or more floating diffusion region(s) 108 is formed in the substrate 102 and between the adjacent pixel regions 103. The respective transfer gate 106 may be laterally between the photodetector 104 and the floating diffusion region 108. For example, the respective transfer gate 106 is configured to transfer the accumulated charge from the photodetector 104 to the floating diffusion region 108 during the operation.

With continued reference to FIG. 1, the first tier 100 may include one or more deep p-well (DPW) region(s) 107 formed in the substrate 102. For example, the DPW region 107 is adjacent to, and at least partially surrounds, the respective photodetector 104. The DPW region 107 may include a circle or ring shape in a top-down view (not shown). In some embodiments, the DPW region 107 is doped with p-type dopants. A portion of the DPW region 107 may be directly below the floating diffusion region 108. In some embodiments, the portion of the DPW region 107 is connected to the bottom of the floating diffusion region 108.

With continued reference to FIG. 1, the first tier 100 may include an interconnect structure 112 formed over the front side 102a of the substrate 102. For example, the interconnect structure 112 includes an interlayer dielectric (ILD) layer 1121 and conductive features 1122 formed in the ILD layer 1121. In some embodiments, the ILD layer 1121 includes an oxide, a nitride, a combination thereof, or other suitable dielectric material(s). The conductive features 1122 may include conductive lines, conductive vias, contact pads, etc. For example, a first conductive via of the conductive features 1122 extends from the gate electrode layer 1063 of the respective transfer gate 106 to another one of conductive features 1122. In some embodiments, a second conductive via of the conductive features 1122 extends from the floating diffusion region 108 to another one of conductive features 1122.

Still referring to FIG. 1, the first tier 100 may include a bonding structure 114 formed over the interconnect structure 112. For example, the bonding structure 114 includes a bonding dielectric layer 1141 and bonding features 1142 laterally covered by the bonding dielectric layer 1141. In some embodiments, the bonding dielectric layer 1141 includes an oxide or other suitable bonding material(s). The respective bonding feature 1142 may be formed in a pad form, a via form, or a combination thereof, etc. The bonding features 1142 may be electrically coupled to the transfer gate 106 through the conductive features 1122 of the interconnect structure 112. In some embodiments, a top surface 1141t of the bonding dielectric layer 1141 is substantially leveled with top surfaces 1142t of the bonding features 1142, within process variations. The top surface 1141t of the bonding dielectric layer 1141 and the top surfaces 1142t of the bonding features 1142 may be collectively viewed as a bonding surface 114t of the first tier 100. In some embodiments, the bonding surface 114t is substantially flat by performing a planarization process (e.g., chemical mechanical polishing, grinding, etching, a combination thereof, etc.) on the bonding structure 114.

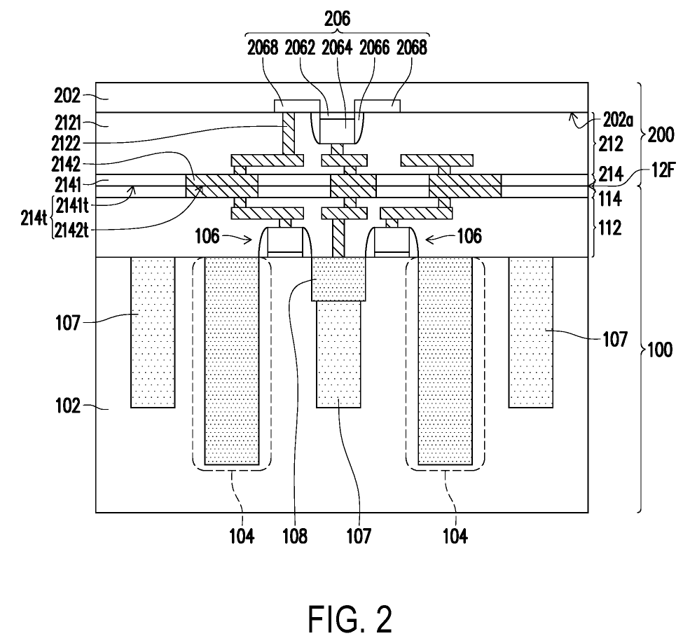

Referring to FIG. 2 and with reference to FIG. 1, a second tier 200 may be provided. For example, the second tier 200 includes a substrate 202 and one or more transistor(s) 206 formed in/on a front side 202a of the substrate 202. For example, the substrate 202 includes a bulk silicon substrate, a silicon-on-insulator (SOI) substrate, or another suitable semiconductor substrate. The respective transistor 206 may include a pair of source/drain (S/D) regions 2068 formed in the substrate 202, a gate dielectric layer 2062 formed over the front-side 202a of the substrate 202, and a gate electrode layer 2064 formed on the gate dielectric layer 2062. In some embodiments, sidewall spacers 2066 are formed on opposing sides of the gate electrode layer 2064 and opposing sidewalls of the gate dielectric layer 2062.

With continued reference to FIG. 2, the second tier 200 may include an interconnect structure 212 formed over the front side 202a of the substrate 202. For example, the interconnect structure 212 includes an ILD layer 2121 and conductive features 2122 formed in the ILD layer 2121. In some embodiments, the ILD layer 2121 includes an oxide, a nitride, a combination thereof, or other suitable dielectric material(s). The conductive features 2122 may include conductive lines, conductive vias, contact pads, etc. For example, a first conductive via of the conductive features 2122 extends from the gate electrode layer 2064 of the respective transistor 206 to another one of conductive features 2122. In some embodiments, a second conductive via of the conductive features 2122 extends from the S/D region 2068 of the respective transistor 206 to another one of conductive features 2122.

With continued reference to FIG. 2, the second tier 200 may include a bonding structure 214 formed on the interconnect structure 212 and electrically coupled to the transistor(s) 206 through the interconnect structure 212. For example, the bonding structure 214 includes a bonding dielectric layer 2141 and bonding features 2142 laterally covered by the bonding dielectric layer 2141. In some embodiments, the bonding dielectric layer 2141 includes an oxide or other suitable bonding material(s). The respective bonding feature 2142 may be formed in a pad form, a via form, or a combination thereof, etc. The bonding features 2142 may be electrically coupled to the transistor(s) 206 through the conductive features 2122 of the interconnect structure 212. In some embodiments, a top surface 2141t of the bonding dielectric layer 2141 is substantially leveled with top surfaces 2142t of the bonding features 2142, within process variations. The top surface 2141t of the bonding dielectric layer 2141 and the top surfaces 2142t of the bonding features 2142 may be collectively viewed as a bonding surface 214t of the second tier 200. In some embodiments, the bonding surface 214t is substantially flat by performing the planarization process on the bonding structure 214.

Still referring to FIGS. 2 and 1, the second tier 200 may be bonded to the first tier 100. For example, the bonding structure 214 of the second tier 200 is bonded to the bonding structure 114 of the first tier 100. The bonding of the second tier 200 to the first tier 100 may involve dielectric-to-dielectric (e.g., oxide-to-oxide) bonding and metal-to-metal (e.g., copper-to-copper) bonding. For example, the bonding dielectric layer 2141 is fused to the bonding dielectric layer 1141, and the bonding features 2142 are bonded to the bonding features 1142 with one-to-one correspondence. The transistor(s) 206 included in the second tier 200 may be electrically coupled to the first tier 100 through the bonding structures 214 and 114. In some embodiments, the bonding interface 12F of the first tier 100 and the second tier 200 is substantially flat, within process variations. In some embodiments, the second tier 200 is an application-specific integrated circuit (ASIC) configured to process electrical signals received from the first tier 100.

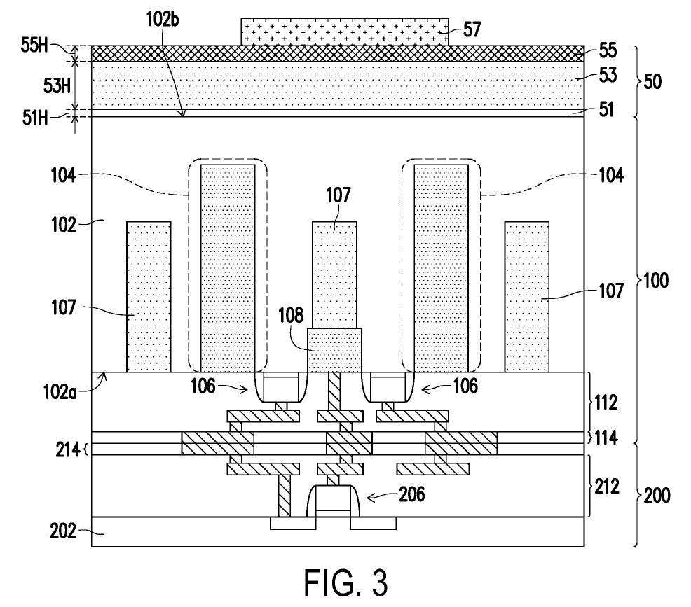

Referring to FIG. 3 and with reference to FIG. 2, a mask structure 50 may be formed over a back side 102b of the substrate 102 opposite to the front side 102a. The mask structure 50 may include one or more masking layer(s). For example, an insulating layer 51 is formed on the back side 102b of the substrate 102. The insulating layer 51 may be an oxide, a nitride, (e.g., silicon oxide), a nitride, an oxy-nitride, a combination thereof, or some other suitable insulating material(s). In some embodiments, a first masking layer 53 and a second masking layer 55 are sequentially stacked over the insulating layer 51. The material of the first masking layer 53 may be different from that of the underlying insulating layer 51, and the material of the second masking layer 55 may be different from that of the underlying first masking layer 53.

In some embodiments, the first masking layer 53 is thicker than the overlying second masking layer 55. For example, the first masking layer 53 has a thickness 53H which is at least four times greater than a thickness 55H of the second mask layer 55. The thickness 51H of the insulating layer 51 may be less than the thickness 53H of the first masking layer 53 and also less than the thickness 55H of the second mask layer 55. In some embodiments, the thickness 53H of the first masking layer 53 is about a hundred times of the thickness 51H of the insulating layer 51. It is realized that the thicknesses provided herein are examples and may be changed to other suitable values depending on process and product requirements.

With continued reference to FIG. 3, a patterned layer 57 may be formed on the second masking layer 55. The patterned layer 57 may be a photoresist. For example, a photoresist material layer is formed over the second masking layer 55, and then a patterning process (e.g., exposure and development or the like) is performed to partially remove the photoresist material layer. The remaining photoresist material may serve as the patterned layer 57 which is configured to protect the underlying portion of the second masking layer 55.

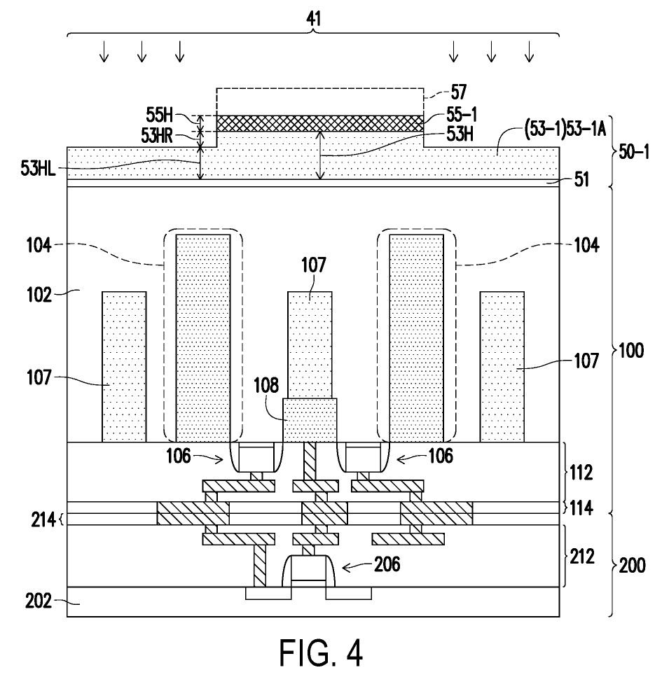

Referring to FIG. 4 and with reference to FIG. 3, a first patterning process 41 may be performed on the mask structure 50 to form a mask structure 50-1. For example, the first patterning process 41 includes lithography, etching, and/or other suitable removal process. During the first patterning process 41, a portion of the second masking layer 55 may be removed to form a second masking pattern 55-1. For example, a portion of the second masking layer 55 which is unmasked by the patterned layer 57 is removed, and the remaining portion of the second masking layer 55 forms the second masking pattern 55-1. In some embodiments, during the first patterning process 41, a portion of the first masking layer 53 underlying the removed portion of the second masking layer 55 is etched away to form a lower portion 53-1A of the first masking layer 53-1.

After the first patterning process 41, the patterned layer 57 may be removed from the second masking pattern 55-1 using, e.g., an ashing process followed by a wet clean process. Other removal process may be used depending on the material of the patterned layer 57. The patterned layer 57 is outlined by the dashed box to indicate it is removed after forming the lower portion 53-1A of the first masking layer 53-1 and the second masking pattern 55-1.

With continued reference to FIG. 4, the lower portion 53-1A of the first masking layer 53-1 may have a stepped cross-sectional profile. For example, the rest part of the lower portion 53-1A which is not covered by the second masking pattern 55-1 has a thickness 53HL less than the thickness 53H of the part of the lower portion 53-1A underlying the second masking pattern 55-1. The difference between the thickness 53H and the thickness 53HL is the thickness 53HR of the removed portion of the first masking layer 53. In some embodiments, the thickness 53HR is less than the thickness 55H of the second masking pattern 55-1. The etch depth of the first masking layer 53 may depend on etching recipe and construe no limitation in the disclosure.

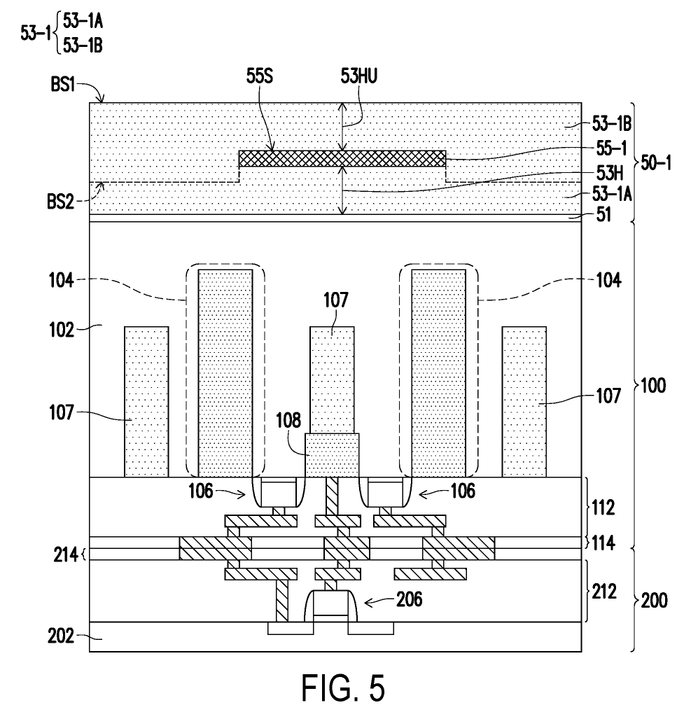

Referring to FIG. 5 and with reference to FIG. 4, an upper portion 53-1B of the first masking layer 53-1 may be formed on the lower portion 53-1A and the second masking pattern 55-1 through suitable deposition process. In some embodiments, the upper portion 53-1B of the first masking layer 53-1 has a substantially flat top surface BS1 and an uneven bottom surface BS2 conformal to the stepped cross-sectional profile of the lower portion 53-1A of the first masking layer 53-1. The thickness 53HU of the upper portion 53-1B measured from the top surface BS1 to the top surface 55S of the second masking pattern 55-1 may be greater than the thickness 53H of the lower portion 53-1A of the first masking layer 53-1. For example, the thickness 53HU of the upper portion 53-1B is at least four times greater than the thickness 53H of the lower portion 53-1A. It is realized that the thicknesses provided herein are examples and may be changed to other suitable values depending on process and product requirements.

In some embodiments, the upper portion 53-1B and the lower portion 53-1A are made of the same material, and thus no visible interface is formed therebetween. Alternatively, the materials of the upper portion 53-1B and the lower portion 53-1A are different. The upper portion 53-1B and the lower portion 53-1A may be collectively viewed as the first masking layer 53-1. The dashed lines between the upper portion 53-1B and the lower portion 53-1A are not shown in the following drawings. In some embodiments, the second masking pattern 55-1 is embedded in the first masking layer 53-1. The second masking pattern 55-1 may be wrapped around by the first masking layer 53-1.

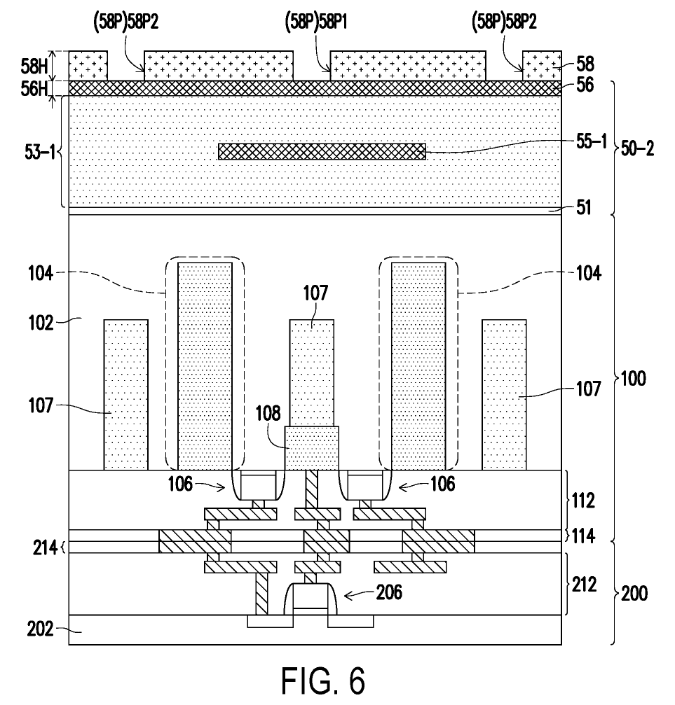

Referring to FIG. 6 and with reference to FIG. 5, a third masking layer 56 may be formed on the first masking layer 53-1 to form a mask structure 50-2. In some embodiments, the third masking layer 56 and the second masking pattern 55-1 are made of the same material. Alternatively, the materials of the third masking layer 56 and the second masking pattern 55-1 are different. The third masking layer 56 may have a thickness 56H substantially equal to the thickness 55H of the second masking pattern 55-1.

In some embodiments, a patterned layer 58 with openings 58P is formed on the third masking layer 56, and portions of the third masking layer 56 are exposed by the openings 58P. The openings 58P may include first opening 58P1 directly over the second masking pattern 55-1 and second openings 58P2 surrounding the first opening 58P1. The second openings 58P2 may be vertically and laterally offset from the second masking pattern 55-1. In some embodiments, the patterned layer 58 has a thickness 58H greater than the thickness 56H of the third masking layer 56. The patterned layer 58 may be a photoresist. For example, a photoresist material layer is formed over the third masking layer 56, and then a portion of the photoresist material layer is removed to form the openings 58P. The remaining photoresist material may serve as the patterned layer 58 which is configured to protect the underlying portion of the third masking layer 56.

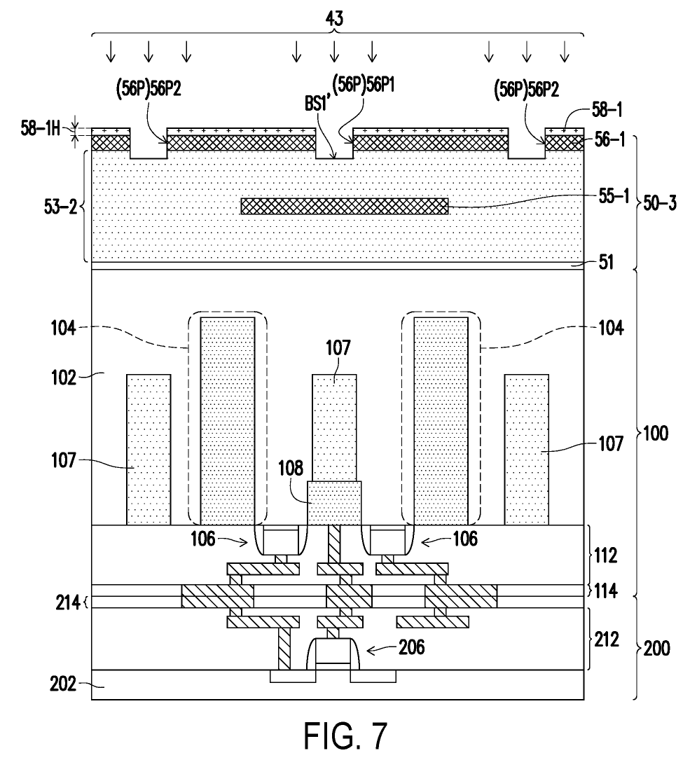

Referring to FIG. 7 and with reference to FIG. 6, a second patterning process 43 may be performed on the mask structure 50-2 to form a mask structure 50-3. For example, the second patterning process 43 includes etching or other suitable removal process. During the second patterning process 43, a portion of the third masking layer 56 may be removed to form a third masking pattern 56-1. For example, the portion of the third masking layer 56 which is unmasked by the patterned layer 58 is removed to form openings 56P underlying the openings 58P (labeled in FIG. 6). For example, the openings 56P includes a first opening 56P1 and second openings 56P2 surrounding the first opening 56P1. The first opening 56P1 may underlie the first opening 58P1 (labeled in FIG. 6) and may be directly over the second masking pattern 55-1. Each second opening 56P2 may underlie one of the second openings 58P2 and may be vertically and laterally offset from the second masking pattern 55-1. The remaining portion of the third masking layer 56 may form the third masking pattern 56-1.

In some embodiments, during the second patterning process 43, a portion of the first masking layer 53-1 underlying the openings 56P of the third masking pattern 56-1 is etched to form a top surface BS1’ of a first masking layer 53-2 having recessed portions, where the recessed portions correspond to the openings 56P. For example, the top surface BS1’ of a first masking layer 53-2 is exposed by the openings 56P of the third masking pattern 56-1. During the second patterning process 43, the patterned layer 58 may be thinned down to form a patterned layer 58-1. For example, the patterned layer 58-1 has a reduced thickness 58-1H less than the thickness 58H (labeled in FIG. 6).

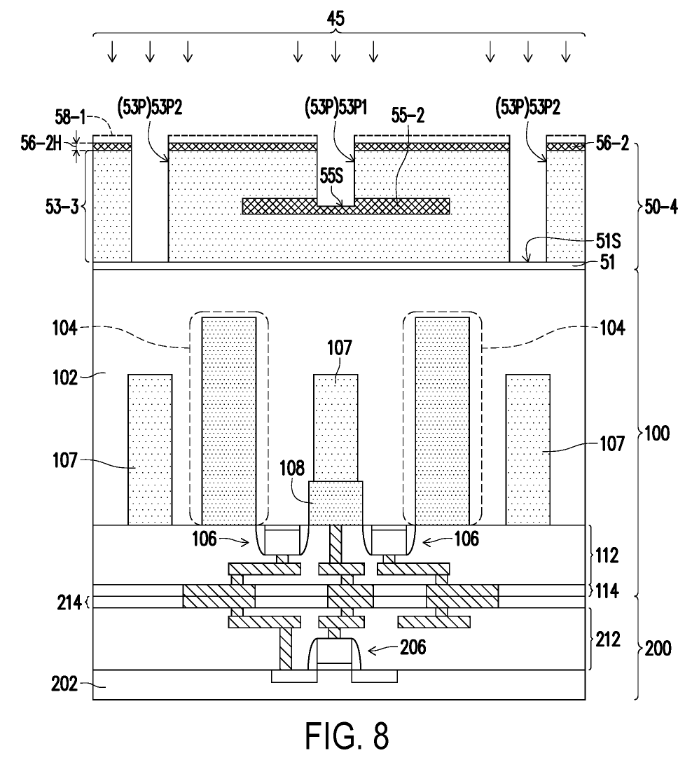

Referring to FIG. 8 and with reference to FIG. 7, a third patterning process 45 may be performed on the mask structure 50-3 to form a mask structure 50-4. For example, the third patterning process 45 includes etching or other suitable removal process. During the third patterning process 45, a portion of the first masking layer 53-2 may be removed to form a first masking layer 53-3 with openings 53P. For example, a portion of the first masking layer 53-2 which is unmasked by the third masking pattern 56-1 is removed to form openings 53P, where the openings 53P underlying the openings 56P (labeled in FIG. 7) of the third masking pattern 56-1. In some embodiments, the openings 53P includes a first opening 53P1 and second openings 53P2 surrounding the first opening 53P1, where the first opening 53P1 underlies the first opening 56P1 (labeled in FIG. 7) and each second opening 53P2 underlies one of the second openings 56P2. In some embodiments, portions of a top surface 51S of the insulating layer 51 are exposed by the second openings 53P2. During the third patterning process 45, a portion of the second masking pattern 55-1 underlying the first opening 53P1 of the first masking layer 53-3 may be etched to form a second masking pattern 55-2 with a recessed top surface 55S. For example, the recessed top surface 55S is exposed by the first opening 53P1 of the first masking layer 53-3.

During or after performing the third patterning process 45, the patterned layer 58-1 may be removed using, e.g., an ashing process followed by a wet clean process. Other removal process may be used depending on the material of the patterned layer 58-1. The patterned layer 58-1 is outlined by the dashed box to indicate it is removed after forming the first masking layer 53-3 with the openings 53P. In some embodiments, during the removal of the patterned layer 58-1, the third masking pattern 56-1 is thinned down to form a third masking pattern 56-2. For example, the third masking pattern 56-2 has a reduced thickness 56-2H less than the thickness 56H (labeled in FIG. 6).

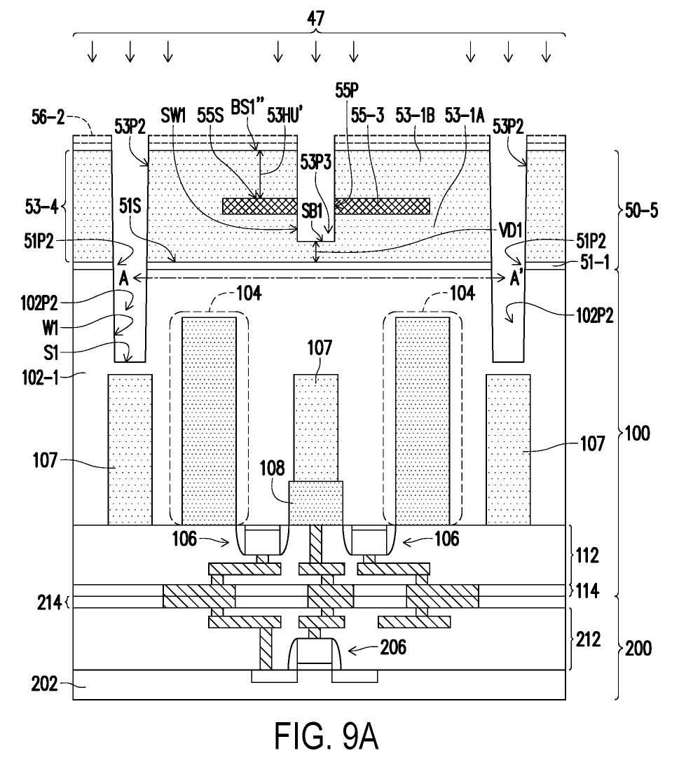

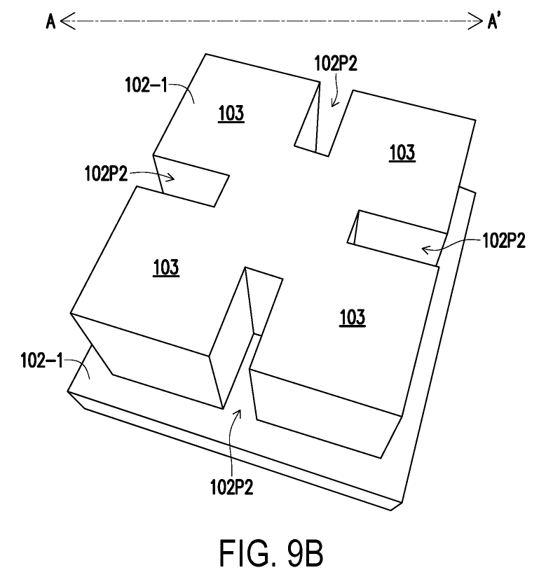

Referring to FIGS. 9A-9B and with reference to FIG. 8, a fourth patterning process 47 may be performed on the mask structure 50-4 to form a mask structure 50-5. For example, the fourth patterning process 47 includes one or more etching processes or other suitable removal processes. In some embodiments, during the fourth patterning process 47, portions of the insulating layer 51 exposed by the second openings 53P2 of the first masking layer 53-3 are removed to form an insulating pattern 51-1 with openings 51P2. In some embodiments, during the fourth patterning process 47, portions of the substrate 102 underlying the openings 51P2 are removed to form a substrate 102-1 with upper openings 102P2. For example, in the cross-sectional view, the respective upper opening 102P2 is defined by a first sidewall W1 and a bottom surface S1 connected to the first sidewall W1. In some embodiments, the bottom surface S1 is directly over the DPW region 107. In some embodiments, the first sidewall W1 is sloped, and the respective upper opening 102P2 has a wider top opening size and a narrower bottom opening size. In the perspective view of FIG. 9B, the upper openings 102P2 may be formed around the pixel regions 103, but the pixel regions 103 are not completely separated from one another at this stage.

In some embodiments, during the fourth patterning process 47, the second masking pattern 55-2 is etched through the first opening 53P1 of the first masking layer 53-3 to form the second masking pattern 55-3. For example, the second masking pattern 55-3 has an opening 55P underlying the first opening 53P1. In some embodiments where the third masking pattern 56-2 and the second masking pattern 55-3 are made of the same material, the third masking pattern 56-2 is removed when forming the opening 55P. The third masking pattern 56-2 is outlined by the dashed box to indicate that it is removed during/after forming the opening 55P.

With continued reference to FIG. 9A, during the fourth patterning process 47, a part of the lower portion 53-1A of the first masking layer 53-3 underlying the opening 55P may be removed to form a recess 53P3. For example, the recess 53P3 is defined by a sidewall SW1 and a bottom surface SB1 connected to the sidewall SW1 of the lower portion 53-1A. A vertical distance VD1 may be measured between the bottom surface SB1 of the lower portion 53-1A and the top surface 51S of the insulating pattern 51-1, where the vertical distance VD1 may be non-zero. When forming the opening 53P3, a part of the upper portion 53-1B of the first masking layer 53-3 may be removed to form a first masking layer 53-4. The removed part of the upper portion 53-1B is outlined by the dashed box to indicate that it is removed during/after forming the opening 53P3. For example, after removing the part of the upper portion 53-1B, the remaining part of the upper portion 53-1B has a thickness 53HU’ measured from the top surface BS1” of the first masking layer 53-4 to the top surface 55S of the second masking pattern 55-3.

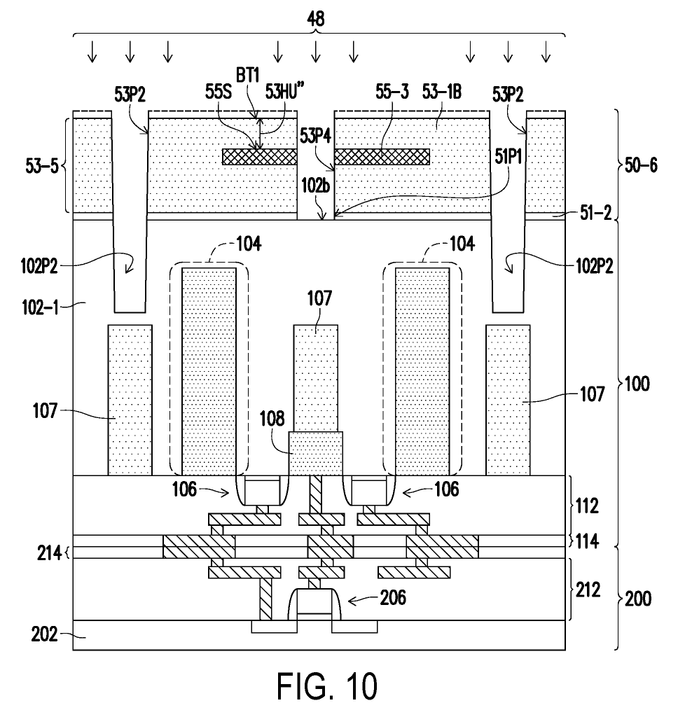

Referring to FIG. 10 and with reference to FIG. 9A, a fifth patterning process 48 may be performed on the mask structure 50-5 to form a mask structure 50-6. For example, the fifth patterning process 48 includes one or more etching processes or other suitable removal processes. A wet etching process or a dry etching process may be used. In some embodiments, the first masking layer 53-4 is etched through the opening 53P3 to form a first masking layer 53-5. For example, the first masking layer 53-5 includes a first opening 53P4 and the second openings 53P2 surrounding the first opening 53P4, where the first opening 53P4 extends through the second masking pattern 55-3. In some embodiments, when forming the opening 53P4, a part of the upper portion 53-1B of the first masking layer 53-4 may be removed. The removed part of the upper portion 53-1B is outlined by the dashed box to indicate that it is removed during/after forming the opening 53P3. For example, after removing the part of the upper portion 53-1B, the remaining part of the upper portion 53-1B has a thickness 53HU” measured from the top surface BT1 of the first masking layer 53-5 to the top surface 55S of the second masking pattern 55-3, where the thickness 53HU” is less than the thickness 53HU’ (labeled in FIG. 9A).

In some embodiments, during the fifth patterning process 48, a portion of the insulating pattern 51-1 exposed by the first opening 53P4 of the first masking layer 53-5 is removed to form an insulating pattern 51-2 with an opening 51P1. For example, the back side 102b of the substrate 102 is exposed by the opening 51P1. In some embodiments, the etchant used in the fifth patterning process 48 is selected, such that only the mask structure 53-4 is etched while the material of the substrate 102-1 remains substantially intact. For example, the back side 102b of the substrate 102 is not recessed after the fifth patterning process 48. The profile of the respective upper opening 102P2 may keep substantially the same before and after the fifth patterning process 48. This may ensure the uniformity of the subsequently-formed through trenches across the substrate.

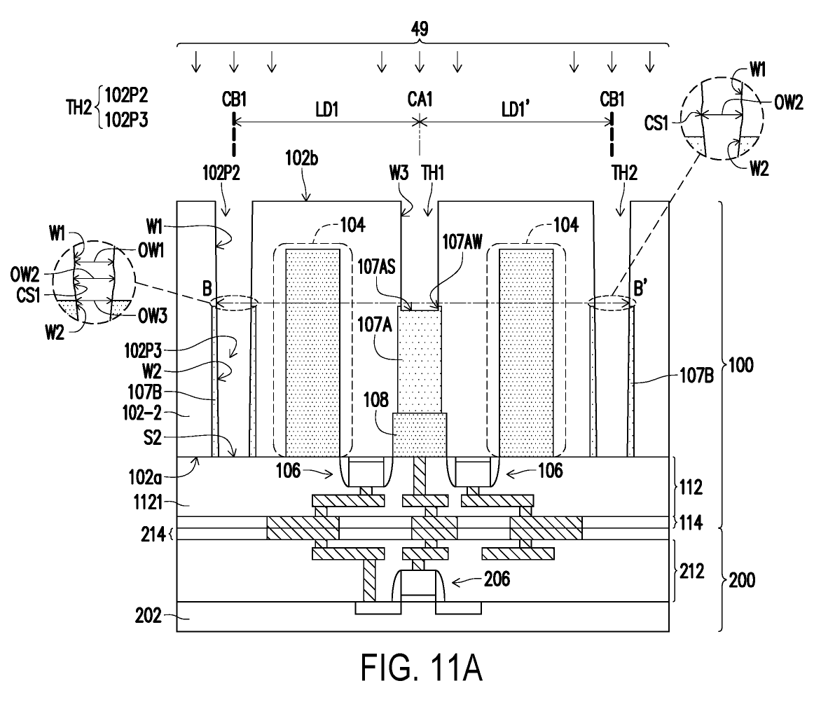

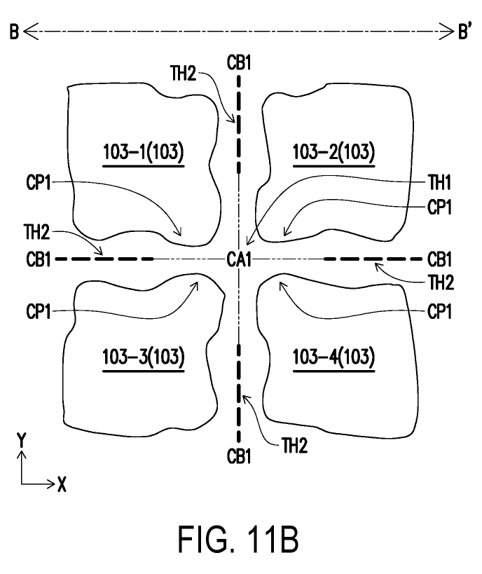

Referring to FIG. 11A and with reference to FIG. 10, a sixth patterning process 49 may be performed on the structure shown in FIG. 10. The sixth patterning process 49 may include one or more etching processes or other suitable removal processes. For example, during the sixth patterning process 49, the substrate 102-1 and the underlying DPW region 107 are etched through the second openings 53P2 and the upper openings 102P2 to form DPW regions 170B and lower openings 102P3 penetrating through the DPW regions 170B. The respective upper opening 102P2 and the underlying lower opening 102P3 may be collectively viewed as a through trench TH2. The respective through trench TH2 may extend from the back side 102b of the substrate 102-2 to the front side 102a of the substrate 102-2. In some embodiments, a portion of the ILD layer 1121 of the interconnect structure 112 is exposed by the lower opening 102P3 of the respective through trench TH2. For example, the respective lower opening 102P3 is defined by a second sidewall W2 and a surface S2 of the ILD layer 1121 connected to the second sidewall W2. In some embodiments, the second sidewall W2 includes a sidewall of the substrate 102-2 and a sidewall of the DPW region 107B connected to the sidewall of the substrate 102-2. In alternative embodiments, the second sidewall W2 is the sidewall of the DPW region 107B. In some embodiments, the second sidewall W2 is sloped, and the respective lower opening 102P3 has a wider top opening size and a narrower bottom opening size. As a whole, the respective through trench TH2 may be wide at the top and narrow at the bottom.

The intersection of the upper opening 102P2 and the underlying lower opening 102P3 is illustrated in the enlarged view circled by the dashed frame of FIG. 11A. For example, a concave surface CS1 is formed at the intersection of the upper opening 102P2 and the lower opening 102P3 and connected to the first sidewall W1 and the second sidewall W2. In some embodiments, in the beginning of the sixth patterning process 49, the bottom surface S1 of the substrate 102-1 starts to be etched, which may enlarge the bottom of the upper opening 102P2. This may result in the formation of the concave surface CS1 laterally concave toward the substrate 102-2. The location of the concave surface CS1 may depend on the terminated point of the fifth patterning process 48. For example, the intersection of the upper opening 102P2 and the lower opening 102P3 has a maximum opening width OW2. The maximum opening width OW2 may be greater than the opening width OW1 of the bottom of the upper opening 102P2 and also greater than the opening width OW3 of the top of the lower opening 102P3.

With continued reference to FIGS. 11A and 10, during the sixth patterning process 49, the substrate 102-1 may be etched through the first opening 53P4 to form a through trench TH1. In some embodiments, the DPW region 107 is recessed through the first opening 53P4 during the sixth patterning process 49 to form a DPW region 107A with a recessed surface 107AS. The DPW region 107A connected to the floating diffusion region 108 may protect the floating diffusion region 108 from being damage during the formation of the through trench TH1. For example, the respective through trench TH1 extends from the back side 102b of the substrate 102-2 to the recessed surface 107AS of the DPW region 107A, and a portion of the DPW region 107A may be exposed by the through trench TH1. The through trench TH1 may be defined by a sidewall W3 of the substrate 102-2, the recessed surface 107AS of the DPW region 107A, and a side surface 107AW of the DPW region 107A connected to the sidewall W3 and the recessed surface 107AS, where the side surface 107AW and the recessed surface 107AS of the DPW region 107A form a recess of the DPW region 107A. In some embodiments, the sidewall W3 of the substrate102-2 and the side surface 107AW of the DPW region 107A are substantially vertical relative to the second sidewall W2 of the substrate 102-2.

Since the respective through trench TH2 passes through the substrate 102-2 while the through trench TH1 ends at the middle of the substrate 102-2, the through trench TH2 may be viewed as a deep through trench TH2 and the through trench TH1 may be viewed as a shallow through trench TH1. In some embodiments, after the sixth patterning process 49, the mask structure 50-6 is removed to expose the back side 102b of the substrate 102-2. Depending on the materials of the mask structure 50-6, any suitable removal technique(s) may be employed.

FIG. 11B is a schematic plan view of the structure taken along the reference cross section B-B’ of FIG. 11A. Referring to FIG. 11B and with reference to FIG. 11A, the deep through trenches TH2 may be in communication with each other through the shallow through trench TH1. For example, the deep through trenches TH2 and the shallow through trench TH1 are all connected in the plan view so as to completely separate the pixel regions (e.g., 103-1, 103-2, 103-3, and 103-4) from one another. The pixel regions (e.g., 103-1, 103-2, 103-3, and 103-4) may be arranged in an array in the plane view. In some embodiments, the center line CA1 of the shallow through trench TH1 is substantially aligned with the center line CB1 of the respective deep through trench TH2 in the plan view. For example, the center line CB1 of the deep through trench TH2 extending along the x-direction is substantially aligned with the center line CA1 of the shallow through trench TH1 extending along the x-direction. A virtual plane on which the center line CB1 along the x-direction is located may be coplanar with a virtual plane on which the center line CA1 along the x-direction is located. Similarly, the center line CB1 of the deep through trench TH2 extending along the y-direction is substantially aligned with the center line CA1 of the shallow through trench TH1 extending along the y-direction. A virtual plane on which the center line CB1 along the y-direction is located may be coplanar with a virtual plane on which the center line CA1 along the y-direction is located.

Still referring to FIGS. 11B and 11A, in the plan view, each pixel region (e.g., 103-1, 103-2, 103-3, or 103-4) may include a corner portion CP1 protruding toward the center point of the center line CA of the shallow through trench TH1. In some embodiments, in the cross-sectional view of FIG. 11A, a lateral distance LD1 between the center line CA1 of the shallow through trench TH1 and the center line CB1 of the deep through trench TH2 at the left hand side is substantially equal to a lateral distance LD1’ between the center line CA1 of the shallow through trench TH1 and the center line CB1 of the deep through trench TH2 at the right hand side.

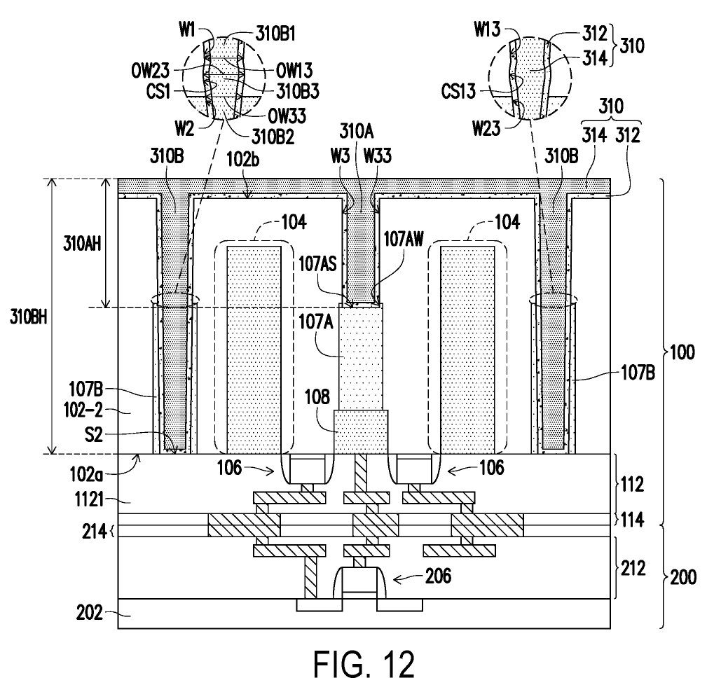

Referring to FIG. 12 and with reference to FIG. 11A, the through trenches TH1 and TH2 may be filled with one or more dielectric layer(s) to form deep trench isolation (DTI) structure 310. Since the DTI structure 310 extends from the back side 102b of the substrate 102-2, the DTI structure 310 may be referred to as a backside DTI (BDTI) structure 310. The DTI structure 310 may be formed at the boundary of the respective pixel region and may thus be referred to as a boundary DTI structure (BDTI) structure 310. For example, the BDTI structure 310 includes a liner layer 312 and a filling dielectric layer 314 overlying the liner layer 312. In some embodiments, the liner layer 312 includes an oxide, a metal oxide, and/or the like. The filling dielectric layer 314 may include an oxide, a nitride, carbide, or a mixture thereof, or another type of dielectric material is used in place of the filling dielectric layer 314. In some embodiments, the liner layer 312 is configured to increase reflectivity of the BDTI structure 310. The filling dielectric layer 314 may function to reflect incident light toward the photodetector 104 to increase the quantum efficiency of the resulting device and to reduce optical crosstalk between the pixels.

The liner layer 312 may be formed in the through trench TH1 to line the first sidewall W1, the second sidewall W2, the concave surface CS1, and the surface S2 of the ILD layer 1121. The liner layer 312 may be formed in the through trench TH2 to line the sidewall W3 of the substrate 102-2 and the recessed surface 107AS and the side surface 107AW of the DPW region 107A. The filling dielectric layer 314 may be formed on the liner layer 312 and fill the rest space of the through trenches TH2 and TH1. In some embodiments, the liner layer 312 extends to form across the back side 102b of the substrate 102-2 and the filling dielectric layer 314 may be formed on the liner layer 312 and over the back side 102b of the substrate 102-2. The liner layer 312 may separate the back side 102b of the substrate 102-2 from the filling dielectric layer 314.

With continued reference to FIGS. 12 and 11, the BDTI structure 310 may include a first portion 310A formed in the through trench TH1 and a second portion 310B formed in the through trench TH2. The second portion 310B may extend further than the first portion 310A within the substrate 102-2. For example, a height 310AHof the first portion 310A is less than a height 310BH of the second portion 310B. As shown in the enlarged view of FIG. 12, the second portion 310B may include a first sloped sidewall W13 interfaced with the first sidewall W1, the second sloped sidewall W23 interfaced with the second sidewall W2, and a convex sidewall CS13 interfaced with the concave sidewall CS1. The second portion 310B formed in the through trench TH2 may be tapered in a direction from the back side 102b toward the front side 102a of the substrate 102-2. The first portion 310A formed in the through trench TH1 may include a sidewall W33 interfaced with the sidewall W3. For example, the sidewall W33 of the first portion 310A is substantially vertical relative to the first sloped sidewall W13 and the second sloped sidewall W23 of the second portion 310B. In some embodiments, a center line of the first portion 310A is substantially aligned with a center line of the second portion 310B in a plan view (e.g., refer to the center lines CA1 and CB1 in FIG. 11B).

Still referring to the enlarged view of FIG. 12, the respective second portion 310B may include an upper part 310B1 having the first sloped sidewall W13, a lower part 310B2 having the second sloped sidewall W33, and an intersection part 310B3 having the convex sidewall CS13. In some embodiments, the upper part 310B1 has a bottom width OW13 less than the maximum width OW23 of the intersection part 310B3. The lower part 310B2 may have a top width OW33 less than the maximum width OW23 of the intersection part 310B3.

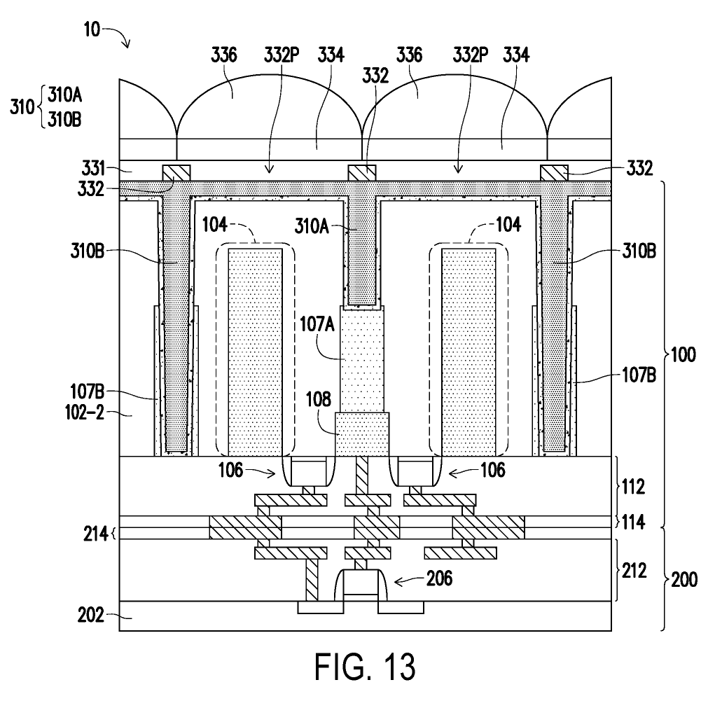

Referring to FIG. 13 and with reference to FIG. 12, a dielectric layer 331 is optionally formed over the back side 102b of the substrate 102-2. The dielectric layer 331 may include one or more passivation material(s) or any suitable dielectric material(s). A grid structure 332 is optionally formed over the first portion 310A and the second portion 310B of the BDTI structure 310 and embedded in the dielectric layer 331. The grid structure 332 may include suitable one or more light-shielding material(s) such as metallic material(s) or the like. The respective opening 332P of the grid structure 332 may be formed above the corresponding photodetector 104 to enable incident light to pass through the grid structure 332 and to the photodetector 104. In some embodiments, one or more light filter regions 334 are formed over the dielectric layer 331 and correspond to the openings 332P of the grid structure 332. For example, each light filter region 334 is disposed directly above one of the openings 332P of the grid structure 332. In some embodiments, micro-lenses 336 are disposed over the light filter regions 334 and configured to focus incident light towards the photodetectors 104.

As shown in FIG. 13, an image sensor device 10 is provided. During operation of the image sensor device 10, the incident radiation (not shown) may be focused by the micro-lens 336 to the underlying pixel regions in which the photodetectors 104 are located. In some embodiments, when incident radiation of sufficient energy strikes the respective photodetector 104, it generates an electron-hole pair that produces a photocurrent. Notably, the image sensor device 10 illustrated in FIG. 13 is provided as an example and other examples may differ from what is described with regard to FIG. 13.

The present disclosure relates to an image sensor device including the BDTI structure with varying heights to improve full well capacity and reduce leakage current, and an associated method of formation. For example, the mask structure (e.g., 50 described in FIGS. 3 to 50-6 described in FIG. 10) is employed to form the through trenches for accommodating the first portion 310A and the second portion 310B of the BDTI structure 310. The mask structure may include the second masking pattern (55-3 labeled in FIG. 9A) and the third masking pattern (56-2 labeled in FIG. 8) below and separated from the second masking pattern by the first masking layer (53-4 labeled in FIG. 9A). The overlying third masking pattern may be configured to define the location of the deep through trench (e.g., the process described in FIG. 9), while the underlying second masking pattern may be configured to define the location of the shallow through trench (e.g., the process described in FIG. 11A). The formation of the shallow through trench and the deep through trench may be completed at the same step (e.g., the process described in FIG. 11A). This may help prevent undesirable effects such as overlap shift with respect to the pixel regions (103-1 to 103-4 labeled in FIG. 11B). For example, the spacing between the center line of the shallow through trench (TH1 labeled in FIGS. 11A-11B) and the center line of the deep through trench (TH2 labeled in FIGS. 11A-11B) are substantially equal. The center line of the deep through trench and the center line of the shallow through trench may be substantially aligned. The pixel regions may be completely spaced apart from one another by the first and second portions of the BDTI structure, in the plane view. The size of each pixel region may be substantially uniform. The reliability and performance of the image sensor device 10 may thus be improved.

In accordance with some embodiments, an image sensor device includes a substrate, photodetectors, and a backside deep trench isolation (BDTI) structure. The substrate includes a front side, a back side opposite to the front side, and pixel regions between the front side and the back side. The photodetectors are disposed in the pixel regions, and the BDTI structure is disposed at a boundary of the respective pixel region. The BDTI structure includes a first portion and second portions, the first portion extends from the back side of the substrate to a first height within the substrate, and the respective second portion includes a second height greater than the first depth. A center line of the first portion is substantially aligned with a center line of the respective second portion in a plan view.

In accordance with some embodiments, an image sensor device includes photodetectors arranged in pixel regions of a substrate, a doped region disposed in the substrate and at a boundary of the respective pixel region, and a dielectric isolation structure disposed in the substrate and at a boundary of the respective pixel region. The doped region includes a first portion and a second portion, and the dielectric isolation structure includes a first portion landing on the first portion of the doped region and a second portion extending further than the first portion in the substrate and passing through the second portion of the doped region. A center line of the first portion is substantially aligned with a center line of the second portion in a plan view.

In accordance with some embodiments, a manufacturing method of an image sensor device includes: forming a mask structure on a back side of a substrate, where the mask structure includes a first masking layer, a second masking pattern embedded in the first masking layer, and a third masking pattern overlying the first masking layer; patterning the substrate using the second masking pattern to form a first through trench; patterning the substrate using the third masking pattern to form a second through trench, where the first through trench is shallower than the second through trench, and a center line of the first through trench is substantially aligned with a center line of the second through trench; and filling the first through trench and the second through trench to respectively form a first portion and a second portion of a backside deep trench isolation (BDTI) structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor device, comprising:
a substrate comprising a front side, a back side opposite to the front side, and pixel regions between the front side and the back side;
photodetectors disposed in the pixel regions;
a backside deep trench isolation (BDTI) structure disposed at a boundary of the respective pixel region, the BDTI structure comprising:
a first portion extending from the back side of the substrate to a first height within the substrate; and
second portions respectively comprising a second height greater than the first depth, wherein a center line of the first portion is substantially aligned with a center line of the respective second portion in a plan view.

2. The image sensor device of claim 1, wherein:
the first portion of the BDTI structure is surrounded by the second portions of the BDTI structure, and
a lateral distance between the center line of the first portion and the center line of one of the second portion is substantially equal to a lateral distance between the center line of the first portion and the center line of adjacent one of the second portion, in a cross-sectional view.

3. The image sensor device of claim 1, wherein a size of the pixel regions is substantially uniform in the plane view.

4. The image sensor device of claim 1, wherein the respective second portion of the BDTI structure comprises:
a first sidewall connected to the back side of the substrate;
a second sidewall between the first side wall and the front side of the substrate; and
a convex sidewall connected to the first sidewall and the second sidewall, the convex sidewall being laterally convex toward the substrate.

5. The image sensor device of claim 1, wherein the respective second portion of the BDTI structure comprises:
a first part extending from the back side of the substrate;
a second part in proximity to the front side of the substrate; and
an intersection part connected to the first part and the second part, wherein a maximum width of the intersection part is greater than a width of the first part and is greater than a width of the second part.

6. The image sensor device of claim 1, further comprising:
a doped region disposed in the substrate and surrounding each of the photodetectors, wherein the respective second portion of the BDTI structure penetrates through the doped region.

7. The image sensor device of claim 6, wherein the first portion of the BDTI structure lands on a recessed surface of the doped region.

8. The image sensor device of claim 6, wherein the doped region comprises a p-type doping concentration.

9. The image sensor device of claim 1, wherein in the plane view, the respective pixel region comprises a corner portion protruding toward the center line of the first portion of the BDTI structure.

10. The image sensor device of claim 1, further comprising:
an interlayer dielectric (ILD) layer disposed on the front side of the substrate, wherein the second portions of the BDTI structure are in contact with the ILD layer.

11. An image sensor device, comprising:
photodetectors arranged in pixel regions of a substrate;
a doped region disposed in the substrate and at a boundary of the respective pixel region, the doped region comprising a first portion and a second portion; and
a dielectric isolation structure disposed in the substrate and at a boundary of the respective pixel region, the dielectric isolation structure comprising:
a first portion landing on the first portion of the doped region; and
a second portion extending further than the first portion in the substrate and passing through the second portion of the doped region, wherein a center line of the first portion is substantially aligned with a center line of the second portion in a plan view.

12. The image sensor device of claim 11, wherein an end of the first portion of the dielectric isolation structure is inserted into the first portion of the doped region.

13. The image sensor device of claim 11, wherein the second portion of the dielectric isolation structure comprises:
a first part laterally covered by the substrate;
a second part laterally covered by the second portion of the doped region; and
a third part connected to the first part and the second part, wherein the third part is wider than the first part and the second part.

14. A manufacturing method of an image sensor device, comprising:
forming a mask structure on a back side of a substrate, wherein the mask structure comprises a first masking layer, a second masking pattern embedded in the first masking layer, and a third masking pattern overlying the first masking layer;
patterning the substrate using the second masking pattern to form a first through trench;
patterning the substrate using the third masking pattern to form a second through trench, wherein the first through trench is shallower than the second through trench, and a center line of the first through trench is substantially aligned with a center line of the second through trench; and
filling the first through trench and the second through trench to respectively form a first portion and a second portion of a backside deep trench isolation (BDTI) structure.

15. The manufacturing method of claim 14, wherein forming the second through trench comprises:
forming an upper opening from the back side of the substrate, wherein when forming the upper opening, the second masking pattern is formed; and
forming a lower opening through the upper opening, wherein the lower opening and the first through trench are formed at a same step.

16. The manufacturing method of claim 14, wherein the mask structure further comprises an insulating pattern separating the first masking layer from the back side of the substrate, when forming the upper opening of the second through trench, the insulating pattern protects a portion of the substrate from being etched, and the portion of the substrate is to be etched to form the first through trench.

17. The manufacturing method of claim 14, wherein the second masking pattern and the third masking pattern are made of a same material.

18. The manufacturing method of claim 14, further comprising:
forming photodetectors in the substrate; and
forming a doped region laterally surrounding the respective photodetector before forming the mask structure.

19. The manufacturing method of claim 18, wherein forming the second through trench comprises:
patterning the doped region, wherein the second through trench penetrates through the doped region.

20. The manufacturing method of claim 18, wherein forming the first through trench comprises:
performing an etching process on the substrate, wherein the doped region is recessed after the etching process.
